(19) United States
(12) Patent Application Publication
(10) Pub. No.: US 2023/0317475 A1
(43) Pub. Date: Oct. 5, 2023

(54) PROCESSING APPARATUS AND TEMPERATURE CONTROL METHOD

(71) Applicant: Tokyo Electron Limited, Tokyo (JP)

(72) Inventors: Koji YOSHII, Iwate (JP); Tatsuya YAMAGUCHI, Tokyo (JP)

(21) Appl. No.: 18/185,674

(22) Filed: Mar. 17, 2023

(30) Foreign Application Priority Data
Mar. 31, 2022 (JP) 2022-060751
Jan. 6, 2023 (JP) 2023-001181

(51) Int. Cl. H01L 21/67

(52) U.S. Cl. CPC H01L 21/67109; H01L 21/67248

(57) ABSTRACT

A processing apparatus includes a processing chamber configured to accommodate a substrate, a furnace body, covering a periphery of the processing chamber, and configured to heat the substrate accommodated inside the processing chamber, a gas supply unit configured to supply a cooling gas to a temperature controlling space between the processing chamber and the furnace body, and a gas discharge unit configured to discharge the gas from the temperature controlling space. The gas discharge unit includes a plurality of exhaust holes configured to discharge the gas in the temperature controlling space, located at a plurality of positions along an axial direction of the furnace body in a sidewall of the furnace body.

### CROSS-REFERENCE TO RELATED APPLICATIONS

This application is based upon and claims priority to Japanese Patent Applications No. 2022-060751, filed on Mar. 31, 2022, and No. 2023-001181, filed on Jan. 6, 2023, the entire contents of which are incorporated herein by reference.

### BACKGROUND

### 1. Field of the Invention

The present disclosure relates to processing apparatuses, and temperature control methods.

### 2. Description of the Related Art

For example, Japanese Laid-Open Patent Publication No. 2020-167422 describes a heat treatment apparatus including a processing chamber configured to accommodate a plurality of substrates, and a furnace body provided around the processing chamber and configured to heat the plurality of substrates accommodated inside the processing chamber. The furnace body includes a forced cooling unit (or gas supply unit) and a heat exhaust system (or gas exhaust unit), for the purposes of forcibly cooling the substrates accommodated inside the processing chamber. The gas supply unit includes a plurality of coolant outlets that discharges a gas (or coolant), provided on a sidewall of the furnace body. On the other hand, the gas exhaust unit includes an exhaust port that discharges the gas supplied to a space inside the furnace body, provided at an upper portion of the furnace body.

### SUMMARY

According to one aspect of the present disclosure, a processing apparatus includes a processing chamber configured to accommodate a substrate; a furnace body, covering a periphery of the processing chamber, and configured to heat the substrate accommodated inside the processing chamber; a gas supply unit configured to supply a cooling gas to a temperature controlling space between the processing chamber and the furnace body; and a gas discharge unit configured to discharge the gas from the temperature controlling space, wherein the processing gas discharge unit includes a plurality of exhaust holes configured to discharge the gas in the temperature controlling space, located at a plurality of positions along an axial direction of the furnace body in a sidewall of the furnace body.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a vertical cross sectional view schematically illustrating a configuration of a processing apparatus according to a first embodiment;

FIG. 2A is a vertical cross sectional view schematically illustrating an air flow through a furnace body of FIG. 1;

FIG. 2B is a planar cross sectional view schematically illustrating the air flow through the furnace body illustrated in FIG. 1;

FIG. 3A is a vertical cross sectional view schematically illustrating the furnace body according to a first modification;

FIG. 3B is a vertical cross sectional view schematically illustrating the furnace body according to a second modification;

FIG. 3C is a vertical cross sectional view schematically illustrating the furnace body according to a third modification;

FIG. 4A is a planar cross sectional view schematically illustrating the furnace body according to a fourth modification;

FIG. 4B is a planar cross sectional view schematically illustrating the furnace body according to a fifth modification;

FIG. 4C is a planar cross sectional view schematically illustrating the furnace body according to a sixth modification;

FIG. 5A is a planar cross sectional view schematically illustrating the furnace body according to a seventh modification;

FIG. 5B is a planar cross sectional view schematically illustrating the furnace body according to an eighth modification;

FIG. 5C is a planar cross sectional view schematically illustrating the furnace body according to a ninth modification; and

FIG. 6 is a vertical cross sectional view schematically illustrating a configuration of the processing apparatus according to a second embodiment.

### DETAILED DESCRIPTION

Hereinafter, embodiments and modifications of the present disclosure will be described, with reference to the drawings. In the drawings, the same constituent elements are designated by the same reference numerals, and a redundant description thereof may be omitted.

The present disclosure provides a technique capable of promoting uniform cooling of a processing chamber.

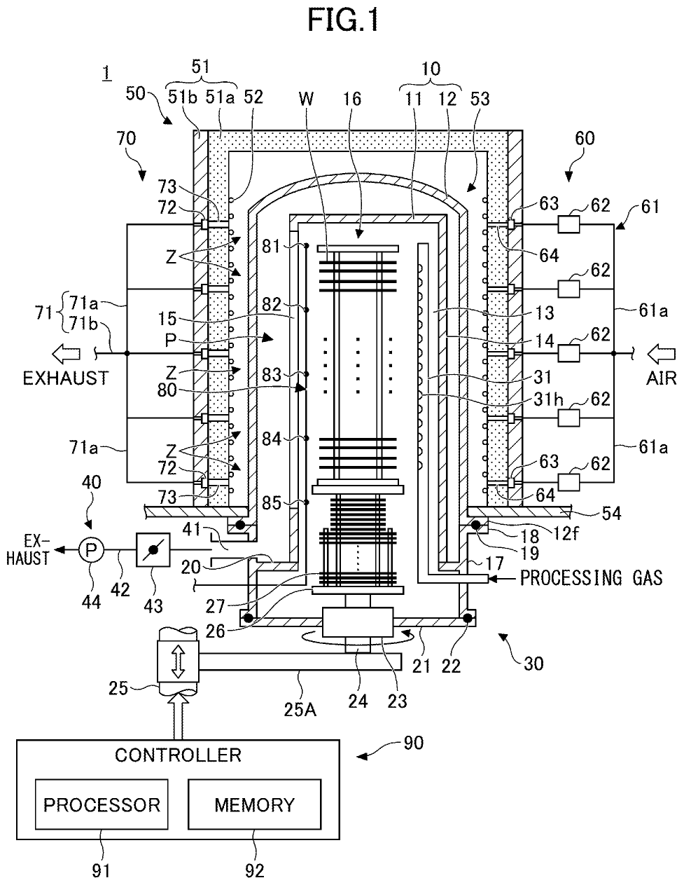

FIG. 1 is a diagram for explaining and schematically illustrating an example of a configuration of a processing apparatus 1 according to a first embodiment. As illustrated in FIG. 1, the processing apparatus 1 according to the first embodiment is a vertical processing apparatus in which a plurality of substrates W is arranged side by side along a vertical direction (that is, axial direction or up-down direction), and a substrate processing, such as film forming process (or deposition process) or the like, is performed on each of the plurality of substrates W. Examples of the substrate W include semiconductor substrates, such as silicon wafers, compound semiconductor wafers, or the like, and glass substrates, for example.

The processing apparatus 1 includes a processing chamber 10 that accommodates the plurality of substrates W, and a cylindrical furnace body 50 that covers a periphery of the processing chamber 10. The processing apparatus 1 further includes a controller 90 that controls an operation of each component of the processing apparatus 1.

The processing chamber 10 is famed to a cylindrical shape having a center axis extending in the vertical direction, in order to arrange the plurality of substrates W side by side along the vertical direction. For example, the processing chamber 10 includes an inner cylinder 11 having a ceiling and an open lower end, and an outer cylinder 12 having a ceiling and an open lower end and covering an outer side of the inner cylinder 11. The inner cylinder 11 and the outer cylinder 12 are famed of a heat-resistant material, such as quartz or the like, and the inner cylinder 11 and the outer cylinder 12 are disposed coaxially so as to form a double cylinder structure. The processing chamber 10 is not limited to the double cylinder structure, and may have a single cylinder structure, or a multiple cylinder structure formed by three or more cylinders.

The celling of the inner cylinder 11 is flat, while the ceiling of the outer cylinder 12 is dome-shaped. An accommodating part 13, that accommodates gas nozzles 31 along the vertical direction, is located at a predetermined position along a circumferential direction of the inner cylinder 11. A portion of a sidewall of the inner cylinder 11 protrudes outward in a radial direction of the inner cylinder 11 to form a convex part 14, and the accommodating part 13 is formed on an inner side of the convex part 14, for example.

An opening 15, that is elongated in the vertical direction, is formed in the sidewall of the inner cylinder 11 on an opposite side from the accommodating part 13. The opening 15 exhausts a gas inside the inner cylinder 11 to a space P between the inner cylinder 11 and the outer cylinder 12. A length of the opening 15 along the vertical direction may be longer than or equal to a length of a wafer boat 16 along the vertical direction.

A lower end of the processing chamber 10 is supported by a cylindrical manifold 17 that is formed of stainless steel, for example. A flange 18 is formed at an upper end of the manifold 17, and the flange 18 supports a flange 12f that is located at the lower end of the outer cylinder 12. A seal member 19 is provided between the flange 12f and the flange 18, so as to hermetically seal the insides of the outer cylinder 12 and the manifold 17.

An annular support part 20 protrudes inward in the radial direction from an inner wall of an upper portion of the manifold 17, and the support part 20 supports the lower end of the inner cylinder 11. A lid 21 is hermetically attached to an opening at a lower end of the manifold 17 via a seal member 22. That is, the lid 21 hermetically closes the opening at the lower end of the manifold 17. The lid 21 is formed of stainless steel into a flat or plate shape, for example.

A rotation shaft 24, that rotatably supports the wafer boat 16 via a magnetic fluid seal 23, penetrates a center portion of the lid 21. A lower portion of the rotation shaft 24 is supported on an arm 25A of an elevator mechanism 25 that is formed by a boat elevator or the like. The processing apparatus 1 can move the lid 21 and the wafer boat 16 up and down integrally with each other, by raising or lowering the arm 25A of the elevator mechanism 25, so that the wafer boat 16 can be inserted into and removed from the processing chamber 10.

A rotation plate 26 is provided at an upper end of the rotation shaft 24, and the wafer boat 16 that is configured to hold the substrates W is placed on the rotation plate 26 via a heat insulation unit 27. The wafer boat 16 is a substrate holder configured to hold the substrates W at predetermined intervals along the vertical direction. Each substrate W is held by the wafer boat 16, so that upper and lower surfaces of each substrate extend in a horizontal direction.

A processing gas supply unit 30 is inserted on an inner side of the processing chamber 10 via the manifold 17. The processing gas supply unit 30 introduces a gas, such as a processing gas, a purge gas, a cleaning gas, or the like, into the inner cylinder 11. For example, the processing gas supply unit 30 includes one or more gas nozzles 31 for introducing the processing gas, the purge gas, and the cleaning gas.

The gas nozzle 31 is an injector pipe formed of quartz, and extends in the vertical direction inside the inner cylinder 11. The gas nozzle 31 is bent into an L-shape at a lower end thereof, and is provided so as to penetrate the manifold 17 from an inside to an outside of the manifold 17. The gas nozzle 31 includes a plurality of gas holes 31h at predetermined intervals along the vertical direction, and discharges the gas in the horizontal direction through each gas hole 31h. For example, the predetermined intervals at which the gas holes 31h are disposed are set to be the same as the predetermined intervals at which the substrates W are supported by the wafer boat 16. In addition, the position of the gas hole 31h along the vertical direction is set to an intermediate position between two adjacent substrates W along the vertical direction, so that the gas can flow smoothly through the space between the adjacent substrates W.

The processing gas supply unit 30 supplies the processing gas and the purge gas to the gas nozzle 31 inside the processing chamber 10, while controlling the flow rate outside the processing chamber 10. An appropriate processing gas may be selected according to a type of film to be deposited on the substrates W. As an example, when forming a silicon oxide film, a silicon-containing gas, such as a dichlorosilane (DCS) gas or the like, and an oxidation gas, such as an ozone (O₃) gas or the like, may be used for the processing gas, for example. An inert gas, such as a nitrogen gas (N₂), an argon gas (Ar) gas, or the like, may be used for the purge gas, for example.

The processing gas exhaust unit 40 exhausts the gas inside the processing chamber 10 to the outside. The gas supplied by the processing gas supply unit 30 flows out from the opening 15 of the inner cylinder 11, into the space P between the inner cylinder 11 and the outer cylinder 12, and is exhausted through a gas outlet 41. The gas outlet 41 is formed in an upper sidewall of the manifold 17, above the support part 20. An exhaust path 42 of the processing gas exhaust unit 40 is connected to the gas outlet 41. The processing gas exhaust unit 40 includes a pressure regulating valve 43 and a vacuum pump 44, in this order from an upstream side to a downstream side of the exhaust path 42. The processing gas exhaust unit 40 controls the pressure inside the processing chamber 10, by causing suction of the gas inside the processing chamber 10 by the vacuum pump 44, and controlling (or regulating) the flow rate of the gas to be exhausted by the pressure regulating valve 43.

In addition, a temperature sensor 80, configured to detect a temperature inside the processing chamber 10, is provided inside the processing chamber 10 (that is, inner cylinder 11). The temperature sensor 80 has a plurality of temperature detecting elements 81 through 85 (five temperature detecting elements in the present embodiment) located at different positions along the vertical direction, in correspondence with a plurality of zones Z that will be described later. A thermocouple, a resistance thermometer sensor, or the like can be used for the plurality of temperature detecting elements 81 through 85. The temperature sensor 80 sends the temperatures detected by the plurality of temperature detecting elements 81 through 85, respectively, to the controller 90.

On the other hand, the furnace body 50 is disposed so as to cover the periphery of the processing chamber 10, and heats and cools the substrates W inside the processing chamber 10. More particularly, the furnace body 50 includes a cylindrical housing 51 having a ceiling, and a heater 52 provided in the housing 51.

The housing 51 is formed to have a diameter and a length in the vertical direction (or axial direction) longer than those of the processing chamber 10, and is disposed so that a center axis of the housing 51 is located at the same position as the center axis of the processing chamber 10. For example, the housing 51 is attached to a base plate 54 that supports the flange 12f of the outer cylinder 12. The housing 51 is attached so as not to make contact with an outer peripheral surface of the processing chamber 10, to thereby foam a temperature controlling space (or temperature adjusting space) 53 between the housing 51 and the processing chamber 10. The temperature controlling space 53 is provided so as to form a continuous space at the side and upper portions of the processing chamber 10.

The housing 51 includes a heat insulating part 51a that is formed to a cylindrical shape having a ceiling and covering the entire processing chamber 10, and a reinforcing part 51b configured to reinforce the heat insulating part 51a at an outer peripheral side of the heat insulating part 51a. That is, a sidewall of the housing 51 has a laminated structure formed by a laminate of the heat insulating part 51a and the reinforcing part 51b. The heat insulating part 51a is famed of a material including silica, alumina, or the like as a main component thereof, for example, and reduces heat transmission in the heat insulating part 51a. The reinforcing part 51b is formed of a metal, such as stainless steel or the like, for example. In addition, in order to reduce the effects of heat to the outside of the furnace body 50, the outer peripheral side of the reinforcing part 51b is covered with a water cooling jacket (not illustrated).

The heater 52 of the furnace body 50 may have an appropriate configuration suited for heating the plurality of substrates W inside the processing chamber 10. For example, an infrared heater, that radiates infrared rays to heat the processing chamber 10, may be used for the heater 52. In this case, the heater 52 may be formed by a wire that is held on an inner wall surface of the heat insulating part 51a via a holder (not illustrated), so as to be held in a spiral shape, an annular shape, an arc shape, a shank shape, a meander shape, or the like on the heat insulating part 51a.

In order to cool the substrates W inside the processing chamber 10, the furnace body 50 according to the present embodiment includes a gas supply unit 60 that supplies a cooling gas to the temperature controlling space 53, and a processing gas discharge unit 70 that discharges the gas in the temperature controlling space 53. Although the gas supplied to the temperature controlling space 53 is air in the present embodiment, the gas is not particularly limited, and an inert gas or the like may be supplied to the temperature controlling space 53.

The gas supply unit 60 ejects air into the processing chamber 10, when forcibly cooling the substrates W after performing a substrate processing (for example, a heat treatment) on the substrates W, for example. The gas supply unit 60 includes an external supply path 61 and flow rate adjusters 62 provided outside the furnace body 50, supply flow paths 63 provided in the reinforcing unit 51b, and supply holes 64 provided in the heat insulating part 51a.

The external supply path 61 is connected to a blower (not illustrated), and supplies the air toward the furnace body 50. The external supply path 61 may be provided with a temperature controller (a heat exchanger, a radiator, or the like) that is configured to control the temperature of the air that is supplied. The external supply path 61 includes a plurality of branch paths 61a at intermediate positions thereof. The plurality of branch paths 61a is arranged along the vertical direction, and is connected to the reinforcing part 51b of the housing 51. Each branch path 61a branches or distributes the air supplied from the blower along the vertical direction.

The flow rate adjuster 62 is provided with respect to each of the plurality of branch paths 61a, and adjusts the flow rate of the air flowing through each branch path 61a. The plurality of flow rate adjusters 62 can vary the flow rate of the air independently of one another under the control of the controller 90. The flow rate adjusters 62 may be configured to adjust the flow rate of the air in response to a manual operation performed by a user or the like, instead of being controlled by the controller 90.

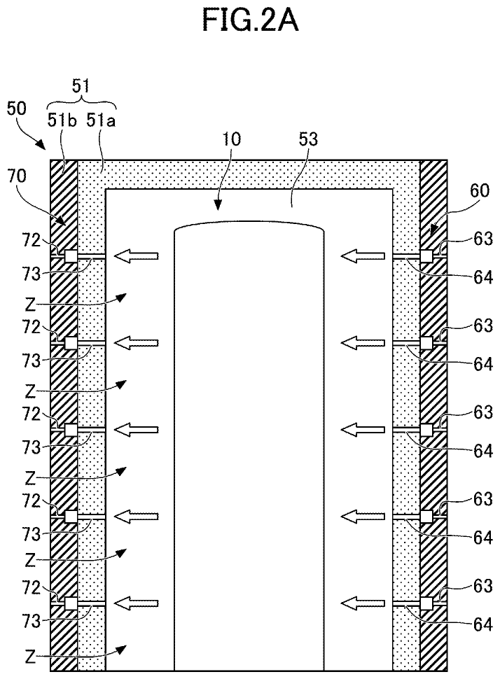

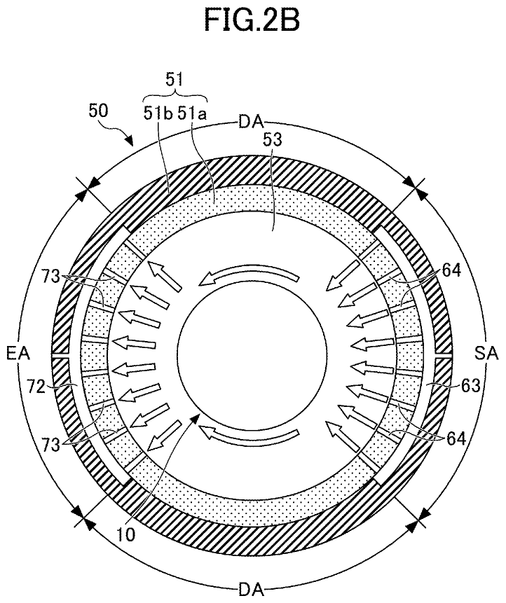

The supply flow path 63 is formed at a plurality of positions along the axial direction (or vertical direction) of the reinforcing part 51b that forms the sidewall of the housing 51. Each of the plurality of supply flow paths 63, in a planar cross sectional view, has an arcuate shape extending along the circumferential direction inside the cylindrical reinforcing part 51b (refer also to FIG. 2B). An arc length of the arcuate shape of each supply flow path 63 is shorter than one-half the circumference of the reinforcing part 51b.

The plurality of supply holes 64 is formed along the axial direction (or vertical direction) of the heat insulating part 51a that forms the sidewall of the housing 51, and is also famed along the circumferential direction of the heat insulating part 51a (refer also to FIG. 2A and FIG. 2B). The supply holes 64 arranged side by side along the axial direction are disposed at the same axial positions as the supply flow paths 63 arranged side by side along the axial direction, and thus communicate with the supply flow paths 63 along the horizontal direction, respectively. The supply holes 64 arranged side by side along the circumferential direction at the same axial position communicate with one supply flow path 63. That is, the plurality of supply holes 64 is provided in a matrix arrangement in a sidewall of the heat insulating part 51a. Each supply hole 64 is formed so as to penetrate the heat insulating part 51a, and ejects the air introduced into each supply flow path 63 toward the temperature controlling space 53.

On the other hand, the processing gas discharge unit 70 discharges the air in the temperature controlling space 53 during the forced cooling, so as to control exhaust heat in the furnace body 50 and an internal pressure of the temperature controlling space 53. The gas discharge unit 70 includes an external exhaust path 71 provided outside the furnace body 50, exhaust flow paths 72 provided in the reinforcing part 51b, and exhaust holes 73 provided in the heat insulating part 51a.

The external exhaust path 71 has a plurality of branch paths 71a from the furnace body 50 to a merging position, and is integrated into a single merged path 71b from the merging position. Each of the plurality of branch paths 71a or the merged path 71b may be provided with a regulating valve or the like for controlling the flow rate of the air to be exhausted. The controller 90 or the user can vary the pressure of the temperature controlling space 53 in the processing gas discharge unit 70, by controlling (or regulating) the flow rate of the air using the regulating valve. In addition, the merged path 71b may be provided with a cooling device (not illustrated) for cooling the air to be discharged, and a pump (not illustrated) for air suction. Further, a downstream end of the merged path 71b may be connected to the external supply path 61. Hence, the processing gas supply unit 60 and the processing gas discharge unit 70 can circulate the air for cooling the furnace body 50. Alternatively, the external exhaust path 71 may discard the air exhausted from the furnace body 50 as waste, without reusing the exhausted air.

Similar to the supply flow path 63, the exhaust flow path 72 is formed at a plurality of positions along the axial direction (or vertical direction) of the reinforcing part 51b that forms the sidewall of the housing 51. Each of the plurality of exhaust flow paths 72, in the planar cross sectional view, has an arcuate shape extending along the circumferential direction inside the cylindrical reinforcing part 51b (refer also to FIG. 2B).

The plurality of exhaust holes 73 according to the present embodiment is formed along the axial direction (or vertical direction) of the heat insulating part 51a that foams the sidewall of the housing 51, and is also formed along the circumferential direction of the heat insulating part 51a (refer also to FIG. 2A and FIG. 2B). The exhaust holes 73 arranged side by side along the axial direction are disposed at the same axial positions as the exhaust flow paths 72 arranged side by side along the axial direction, and thus communicate with the exhaust flow paths 72 along the horizontal direction, respectively. The exhaust holes 73 arranged side by side along the circumferential direction at the same axial position communicate with one exhaust flow path 72. That is, the plurality of exhaust holes 73 is also provided in a matrix arrangement in the sidewall of the heat insulating part 51a.

More specifically, as illustrated in FIG. 2B, the furnace body 50, in the planar cross sectional view, has a supply area SA including the plurality of supply holes 64, an exhaust area EA including the plurality of exhaust holes 73, and a pair of dividing areas DA including no holes. The supply area SA and the exhaust area EA are provided at positions opposite to each other with reference to the center axis of the furnace body 50, and form symmetrical planar shapes. The two dividing areas DA are disposed between the supply area SA and the exhaust area EA, respectively.

In FIG. 2B, the supply area SA, the exhaust area EA, and the two dividing areas DA are set ranges of 90° along the circumferential direction of the furnace body 50. The ranges of the supply area SA, the exhaust area EA, and the two dividing areas DA are not particularly limited. For example, the supply area SA and the exhaust area EA may be set to a range greater than or equal to 90°, and the two dividing areas DA may be set to a range less than 90°. Alternatively, the supply area SA and the exhaust area EA may be set in a range less than 90°, and the two dividing areas DA may be set in a range greater than or equal to 90°.

The supply area SA includes the plurality of supply holes 64 along the circumferential direction of the heat insulating part 51a of the furnace body 50, so that the air is ejected from the entire area of the supply area SA to the temperature controlling space 53. The outer side of each supply hole 64 communicates to the supply flow path 63 extending in the circumferential direction, and the inner side of each supply hole 64 communicates to the temperature controlling space 53. Each supply hole 64 extends linearly along a radial direction of the furnace body 50. Moreover, the supply holes 64 are arranged at equally spaced intervals in the supply area SA. Although the supply area SA illustrated in FIG. 2B includes eight supply holes 64, the number of the supply holes 64 included in the supply area SA is not particularly limited.

The exhaust area EA includes the plurality of exhaust holes 73 along the circumferential direction of the heat insulating part 51a of the furnace body 50, so that the air in the temperature controlling space 53 is ejected from the entire exhaust area EA. The outer side of each exhaust hole 73 communicates to the exhaust flow path 72 extending in the circumferential direction, and the inner side of each exhaust hole 73 communicates to the temperature controlling space 53. Each exhaust hole 73 extends linearly along the radial direction of the furnace body 50. In addition, the supply holes 64 are arranged at equally spaced intervals in the exhaust area EA. Although the exhaust area EA illustrated in FIG. 2B includes eight exhaust holes 73, which is the same as the number of (that is, eight) supply holes 64 included in the supply area SA, the number of the exhaust holes 73 is of course not particularly limited.

As illustrated in FIG. 2A, the supply holes 64 and the exhaust holes 73 arranged side by side along the axial direction in the sidewall of the furnace body 50, respectively, are provided for each of a plurality of zones Z set in the axial direction of the processing chamber 10 (or temperature controlling space 53). In FIG. 2A, five zones Z are set according to the temperature detecting elements 81 though 85 of the temperature sensor 80. A boundary of the zone Z is set approximately at an intermediate position between two adjacent temperature detecting elements among the temperature measuring elements 81 to 85 arranged in the axial direction (an intermediate position between two adjacent exhaust holes among the exhaust holes 73 arranged in the axial direction). However, the zones Z of the temperature controlling space 53 in the present embodiment are not physically partitioned, and are virtual zones communicating with one another.

In each of the zones Z arranged side by side along the axial direction of the furnace body 50, the axial position of the supply hole 64 and the axial position of the exhaust hole 73 are set to the same axial position. The term “same position” as used herein in the present specification includes a case where the positions slightly differ (within a range of 5 cm, for example) along the vertical direction. For example, depending on the arrangement of the heater 52 on the inner wall surface of the insulating part 51a, the positions of the supply holes 64 and the position of the exhaust holes 73 may be deviated from one another along the vertical direction, so as to avoid the position of the heater 52. In the case where the heater 52 is provided in a spiral shape, the positions of the supply holes 64 and the positions of the exhaust holes 73 can be regarded as being the same during one turn, even if the positions along the vertical direction gradually change along the spiral shape. By positioning the supply holes 64 and the exhaust holes 73 at the same position, the processing apparatus 1 can move the air supplied from the supply holes 64 to the temperature controlling space 53 in the horizontal direction perpendicular to the axial direction of the furnace body 50, and discharge the air from the exhaust holes 73.

Further, a set range in which the supply holes 64 and the exhaust holes 73 are arranged in the axial direction may be determined, so that all of the substrates W arranged along the axial direction inside the processing chamber 10 are covered within the set range. In other words, the supply holes 64 and the exhaust holes 73 are disposed at positions higher than the uppermost portion of the plurality of substrates W, respectively, and at the positions lower than lowermost portion of the plurality of substrates W, respectively. Hence, the processing apparatus 1 can uniformly supply the air to the axial positions of the processing chamber 10 corresponding to the positions where the substrates W are arranged along the axial direction.

Referring back to the description of FIG. 1, a computer including a processor 91, a memory 92, an input-output interface (not illustrated), or the like can be used for the controller 90 of the processing apparatus 1. The processor 91 is one or a combination of a central processing unit (CPU), a graphics processing unit (GPU), an application specific integrated circuit (ASIC), a field programmable gate array (FPGA), a circuit including a plurality of discrete semiconductors, or the like. The memory 92 is an appropriate combination of a volatile memory and a nonvolatile memory (for example, a compact disk, a digital versatile disk (DVD), a hard disk, a flash memory, or the like).

The memory 92 stores one or more programs for operating the processing apparatus 1, and a recipe, such as process conditions or the like of the substrate processing. The processor 91 controls each component of the processing apparatus 1, by reading and executing the one or more programs stored in the memory 92. The controller 90 may be configured by a host computer or a plurality of client computers, capable of performing information communication via a network.

The processing apparatus 1 according to the first embodiment is basically configured as described above, and the operation thereof will be described below.

In the substrate processing, the controller 90 of the processing apparatus 1 first transports the wafer boat 16 carrying the plurality of substrates W into the processing chamber 10. By closing the opening at the lower end of the manifold 17 with the lid 21 when the wafer boat 16 is transported into the processing chamber 10, the inside of the processing chamber 10 becomes a hermetically sealed space. After forming the hermetically sealed space, the processing apparatus 1 performs a predetermined substrate processing.

For example, when performing a film forming process (or deposition process) as the substrate processing, the controller 90 controls the heater 52 of the furnace body 50 to raise the temperature of the heater 52 to a set temperature, to thereby heat each of the substrates W inside the processing chamber 10 to a temperature required for the film forming process (annealing step: step (a)). Further, in addition to the annealing process, the controller 90 controls the operation of the processing gas supply unit 30 to supply the processing gas for the film foaming process into the processing chamber 10 through the gas nozzle 31, and exhaust the processing gas inside the processing chamber by the processing gas exhaust unit 40 (processing gas flowing step). Hence, in a state where the pressure inside the processing chamber 10 is maintained at a set pressure, the processing chamber 10 is filled with the processing gas, and a film is formed on the surfaces of each of the substrates W. In addition, the processing apparatus 1 can change the type of processing gas during the film forming process, so as to foam a laminate of a plurality of laminated films, or cause a reaction such as oxidation, nitridation, or the like of the film.

After or during the film forming process, the controller 90 controls the processing gas supply unit 60 and the processing gas discharge unit 70 provided in the furnace body 50, to perform a forced cooling of the processing chamber 10, to thereby lower the temperature of each of the substrates W (cooling step: step (b)). In this state, the controller 90 supplies the air from the blower via the external supply path 61, and controls (or adjusts) the flow rate of the air supplied to the temperature controlling space 53 by each of the flow rate adjusters 62. Hence, the air flowing into the furnace body 50 passes through the supply flow path 63, and flows into the temperature controlling space 53 from each of the supply holes 64.

As illustrated in FIG. 2A, the plurality of supply holes 64 provided along the axial direction of the furnace body 50 eject the air for each of the plurality of zones Z of the temperature controlling space 53. On the other hand, the plurality of exhaust holes 73 provided along the axial direction of the furnace body 50 exhausts the air for each of the plurality of zones Z of the temperature controlling space 53. Moreover, as illustrated in FIG. 2B, the plurality of supply holes 64 provided along the circumferential direction of the supply area SA at the same axial position of the furnace body 50 eject the air from the entire supply area SA to the same zone Z. Further, the plurality of exhaust holes 73 provided along the circumferential direction of the exhaust area EA at the same axial position of the furnace body 50 can exhaust the air from the entire exhaust area EA.

The air supplied to the temperature controlling space 53 moves in the horizontal direction in each zone Z, and hits the outer peripheral surface of the processing chamber 10 from the side of the gas supply area SA. In addition, the air flows around the outer peripheral surface of the processing chamber 10, and moves toward the exhaust area EA. That is, the processing apparatus 1 can maintain the flow of the air in the horizontal direction and efficiently cool the processing chamber 10, by continuously supplying the air to flow in the circumferential direction of the outer peripheral surface of the processing chamber 10 and continuously exhausting the air.

A conventional furnace body has one exhaust port in a ceiling or an upper portion of the furnace body. In this case, the air supplied to the temperature controlling space is guided in an upward direction from the temperature controlling space, and the air is heated more toward the upward direction of the processing chamber. In particular, even in a case where a machine difference (temperature difference) occurs in the vertical direction of the processing chamber due to variations in temperature among the substrates W, variations in the temperature control among the zones Z, or the like during the substrate processing, if the air flows in the upward direction, low-temperature air cannot be sufficiently supplied to the outer peripheral surface of the processing chamber. For this reason, in the conventional furnace body, it is difficult to uniformly control the temperature of the processing chamber during the forced cooling, and there is a problem in that unevenness in temperature may occur among the substrates W. If the unevenness in temperatures among the substrate W is large, unevenness may also occur in the substrate processing.

In contrast, in the processing apparatus 1 according to the present embodiment, the plurality of exhaust holes 73 are provided in the axial direction of the furnace body 50, so that the air flows from each of the supply holes 64 to each of the exhaust holes 73 in an approximately horizontal direction of the temperature controlling space 53. Hence, the processing apparatus 1 can uniformly blow the air to the outer peripheral surface along the axial direction of the processing chamber 10, and can uniformly lower the temperature along the axial direction of the processing chamber 10. In other words, according to the configuration of the furnace body 50, the processing apparatus 1 can absorb the effects of the differences among individual components of each apparatus, an assembly error, an apparatus setup environment, or the like, and can improve a reproducibility with respect to a target temperature of the forced cooling.

In addition, the processing apparatus 1 can perform a detailed control, such as supplying a large amount of air to a high-temperature location and supplying a small amount of air to a low-temperature location, by ejecting the air having the flow rate thereof adjusted by each of the flow rate adjusters 62 from each of the supply holes 64 arranged in the axial direction. For this reason, the processing apparatus 1 can increase a temperature control range for each zone Z during the substrate processing, by controlling the flow rate of the air supplied to the temperature controlling space 53, in addition to the heating by the heater 52, during the substrate processing, a temperature change accompanying a process transition, or the like, for example.

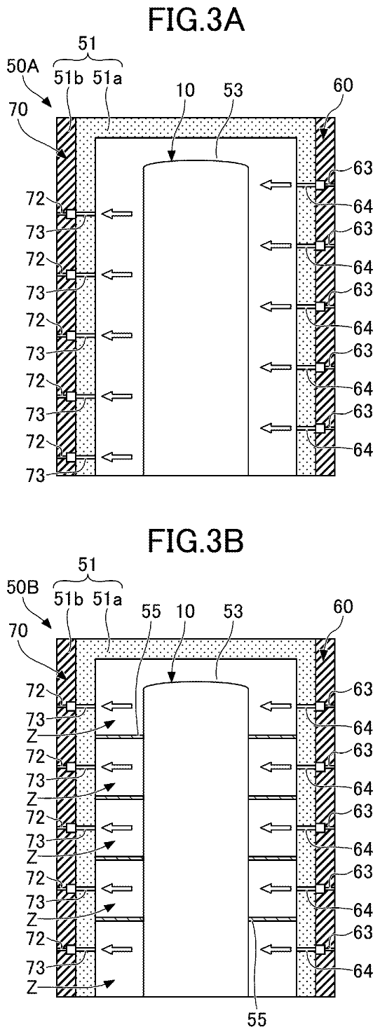

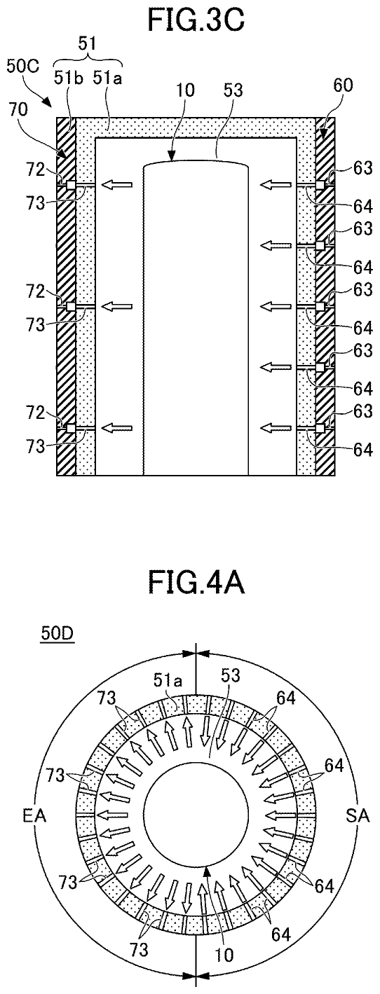

The processing apparatus 1 according to the present disclosure is not limited to the above described embodiment, and various variations and modifications may be made. For example, the directions of the supply holes 64 and the exhaust holes 73 may be parallel to one another, or may be directed outward. Further, the supply holes 64 and the exhaust holes 73 may be disposed in a staggered arrangement within the zone Z in the horizontal direction, for example. Hereinafter, modifications of the processing apparatus 1 will be illustrated and described with reference to FIG. 3A through FIG. 5C.

As illustrated in FIG. 3A, a furnace body 50A according to a first modification differs from the furnace body 50 described above, in that the axial positions of the exhaust holes 73 are different from the axial positions of the supply holes 64. As described above, even when the axial positions of the exhaust holes 73 are deviated from the axial positions of the supply holes 64, the furnace body 50A can supply the air around the outer peripheral surface along the entire axial direction of the processing chamber 10. Accordingly, it is possible to effectively control the temperatures of the entire processing chamber 10 and the substrates W inside the processing chamber 10. In FIG. 3A, each exhaust hole 73 is disposed at an intermediate position between two adjacent supply holes 64 arranged in the axial direction of the furnace body 50A, but the axial position of each of the exhaust holes 73 with respect to each of the supply holes 64 is of course not particularly limited.

As illustrated in FIG. 3B, a furnace body 50B according to a second modification differs from the furnace body 50 described above, in that the supply holes 64 and the exhaust holes 73 are provided for each of the zones Z set in the axial direction of the processing chamber 10 and the furnace body 50B, and a partitioning member 55 partitions (or divides) two adjacent zones Z. Accordingly, in each zone Z partitioned (or divided) by the partitioning members 55, the air flows along the horizontal direction of the zone Z, while the air flows from the supply hole 64 to the exhaust hole 73. Hence, the processing apparatus 1 can control the temperature in more detail for each of the plurality of zones Z, and can promote uniformity of the temperature of each of the substrates W inside the processing chamber 10. Although one supply hole 64 and one exhaust hole 73 are provided along the axial direction of each zone Z in FIG. 3B, the furnace body 50B may be provided with a plurality of supply holes 64 or a plurality of exhaust holes 73 along the axial direction of each zone Z. In addition, the partitioning member 55 may be configured to completely seal a gap between the outer peripheral surface of the processing chamber 10 and the sidewall of the furnace body 50B, or may be installed so that a gap is formed between the outer peripheral surface of the processing chamber 10 and the sidewall of the furnace body 50B.

As illustrated in FIG. 3C, a furnace body 50C according to a third modification differs from the furnace body 50 described above, in that the number of exhaust holes 73 along the axial direction is different from the number of supply holes 64 along the axial direction. That is, the number of the exhaust holes 73 is not limited as long as a plurality of exhaust holes 73 is provided along the axial direction of the furnace body 50C. The number of the exhaust holes 73 along the axial direction may be smaller than the number of the supply holes 64 along the axial direction as illustrated in FIG. 3C, or may be larger than the number of the supply holes 64 along the axial direction.

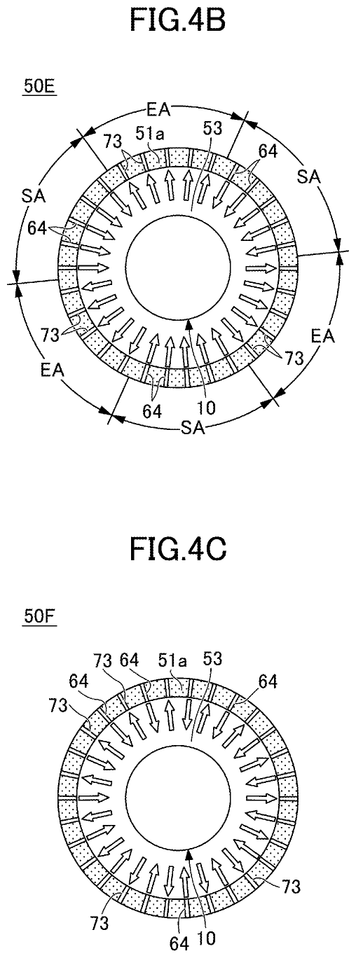

As illustrated in FIG. 4A, a furnace body 50D according to a fourth modification differs from the furnace body 50 described above, in that the furnace body 50D does not include the dividing area DA, includes the gas supply area SA in one half of the heat insulating part 51a in the circumferential direction, and includes the exhaust area EA in the other half of the heat insulating part 51a in the circumferential direction. Even in this configuration having no dividing area DA, the furnace body 50D can perform the ejection of the air into the processing chamber 10, and the exhaust of the air hitting the processing chamber 10, in the same manner as the furnace body 50.

As illustrated in FIG. 4B, a furnace body 50E according to a fifth modification differs from the furnace body 50 described above, in that the supply area SA and the exhaust area EA are alternately repeated a plurality of times along the circumferential direction of the heat insulating part 51a. Thus, the furnace body 50E is not particularly limited as to the arrangement of the supply area SA and the exhaust area EA, and can be freely designed. For example, the gas supply area SA may be disposed to face a portion of the processing chamber 10 where the temperature is likely to rise, and the gas exhaust area EA may be disposed to face other portions of the processing chamber 10, it is possible to directly supply the air to a target portion and easily lower the temperature.

As illustrated in FIG. 4C, a furnace body 50F according to a sixth modification differs from the furnace body 50 described above, in that the supply holes 64 and the exhaust holes 73 are alternately provided along the circumferential direction of the heat insulating part 51a. Even in this configuration in which the supply holes 64 and the exhaust holes 73 are alternately provided, the furnace body 50F can perform the ejection of the air into the processing chamber 10, and the exhaust of the air hitting the processing chamber 10, in the same manner as the furnace body 50.

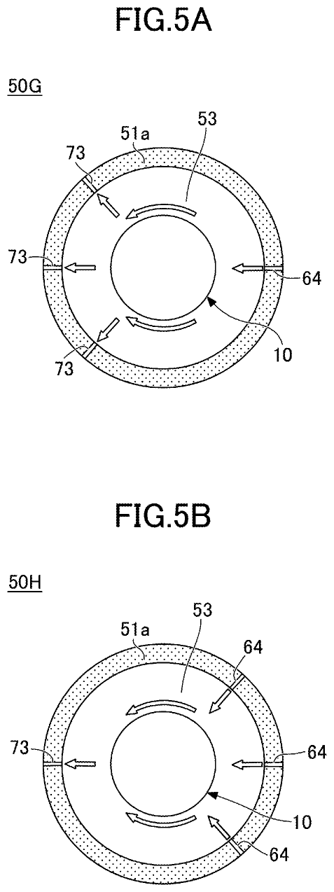

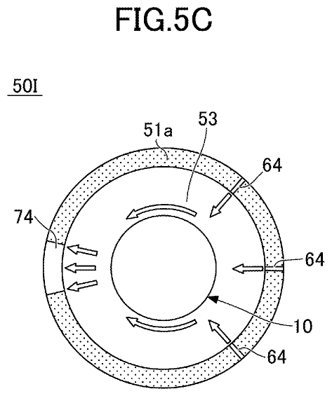

As illustrated in FIG. 5A, a furnace body 50G according to a seventh modification differs from the furnace body 50 described above, in that a single supply hole 64 is provided in the heat insulating part 51a, while a plurality of exhaust holes 73 is provided along the circumferential direction of the heat insulating part 51a. Even in this case, the furnace body 50G can cause the air supplied from the single supply hole 64 to flow around the outer peripheral surface of the processing chamber 10, and exhaust the air from the plurality of exhaust holes 73. Hence, the furnace body 50G can obtain effects similar to those obtainable by the furnace body 50.

As illustrated in FIG. 5B, a furnace body 50H according to an eighth modification differs from the furnace body 50 described above, in that a plurality of supply holes 64 is provided along the circumferential direction of the heat insulating part 51a, while a single exhaust hole 73 is provided along the circumferential direction of the heat insulating part 51a. However, a plurality of exhaust holes 73 is provided along the axial direction of the furnace body 50H. Even in this case, the furnace body 50H can obtain effects similar to those obtainable by the furnace body 50, by causing the air supplied from the plurality of supply holes 64 to flow around the outer peripheral surface of the processing chamber 10, and exhausting the air from the single exhaust hole 73. In other words, it is not essential for the number of the exhaust holes 73 provided along the circumferential direction of the heat insulating part 51a to be the same as the number of the supply holes 64, and the number of exhaust holes 73 may be larger or smaller than the number of the supply holes 64.

As illustrated in FIG. 5C, a furnace body 50I according to a ninth modification differs from the furnace body 50 described above, in that the furnace body 51a includes an elongated exhaust hole 74 elongated along the circumferential direction of the heat insulating part 51a. As described above, by providing the elongated exhaust hole 74, the furnace body 50I can improve an exhaust performance in the circumferential direction. In other words, the shapes of the exhaust holes 73 and 74 are not particularly limited. For example, the furnace body 50I may be provided with an elongated exhaust hole 74 that is elongated along the axial direction and is longer than the supply hole 64 along the axial direction. Alternatively, it is of course possible to freely design the shape of the supply hole 64.

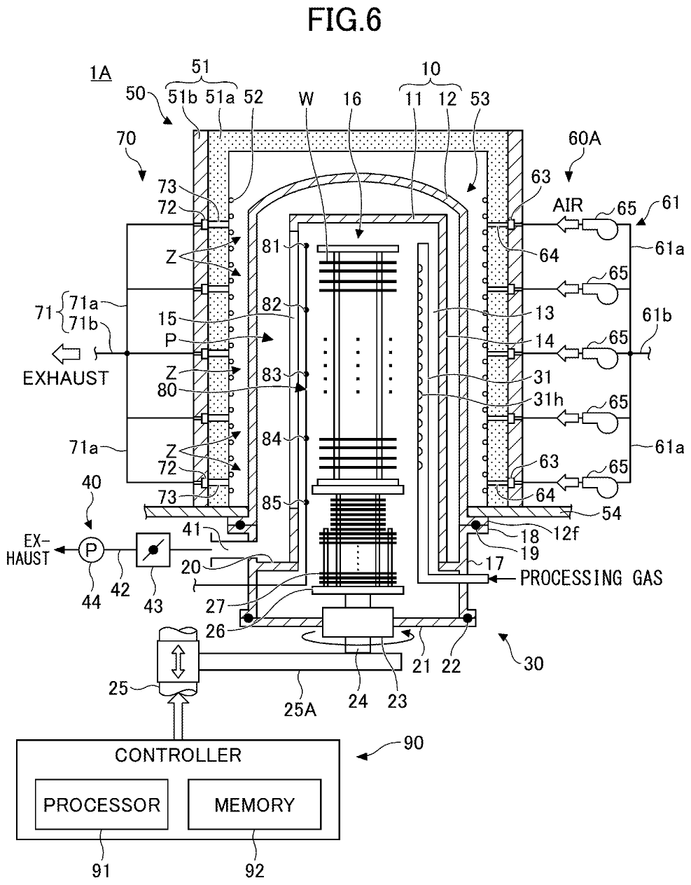

FIG. 6 is a vertical cross sectional view schematically illustrating a configuration of a processing apparatus 1A according to a second embodiment. The processing apparatus 1A according to the second embodiment includes a gas supply unit 60A that differs from the processing gas supply unit 60 of the processing apparatus 1 according to the first embodiment. Otherwise, the configuration of the processing apparatus 1A is the same as that of the processing apparatus 1, and a detailed description of the same configuration will be omitted.

The gas supply unit 60A includes an external supply path 61 and a plurality of blowers (or fan parts) 65 provided outside the furnace body 50, a plurality of supply flow paths 63 provided in the reinforcing part 51b, and a plurality of supply holes 64 provided in the heat insulating part 51a. Similar to the first embodiment, the external supply path 61 includes the plurality of branch paths 61a at intermediate positions thereof, and the plurality of branch paths 61a connects to the plurality of supply flow paths 63 and the plurality of supply holes 64, respectively. The plurality of branch paths 61a is arranged along the vertical direction, and is connected to the reinforcing part 51b of the housing 51. A merged path 61b on an upstream side of the intermediate positions of the external supply path 61 is connected to the external exhaust path 71 (or merged path 71b) of the processing gas discharge unit 70, for example. Because the external supply path 61 is connected to the external exhaust path 71, the processing apparatus 1A can circulate the cooling air, and satisfactorily control the temperature of the temperature controlling space 53 by the circulated air, to thereby reduce effects on the environment. Heat exchangers or the like for controlling the temperature of the air may be provided at appropriate positions of the merged paths 61b and 71b. Alternatively, the merged path 61b may be connected to an air source (not illustrated) or an atmosphere releasing part (not illustrated).

Each of the plurality of blowers 65 is provided with respect to each of the plurality of branch paths 61a. Each blower 65 sucks air (or gas) from the upstream side of the external supply path 61, and blows the air at a controlled flow rate to the downstream side of the branch path 61a in which the blower 65 is provided. The blowers 65 can be controlled independently of one another by the controller 90, and the flow rate of the air in each branch path 61a can be controlled individually. A configuration of the fan part is not limited to the blower 65, and for example, a flow rate adjuster, such as a flow regulator, flow controller, or the like, capable of finely adjusting the flow rate of the air may be provided on the downstream side of the blower 65.

In addition, in the processing gas supply unit 60A, the supply flow paths 63 and the supply holes 64 to which the branch paths 61a on the downstream side of the blowers 65 are connected, may be configured in the same manner as in the first embodiment.

The processing apparatus 1A according to the second embodiment is basically configured as described above. Similar to the first embodiment, after or during the film forming process, the processing apparatus 1A controls the processing gas supply unit 60A and the processing gas discharge unit 70 by the controller 90 to forcibly cool the processing chamber 10, to thereby lower the temperature of each of the substrates W (cooling step). In this state, the controller 90 can supply the air at the flow rate controlled for each of the plurality of zones Z by each of the blowers 65. Each blower 65 can stably suck the air from the upstream side, and force-feed the air to the downstream side, so that it is possible to positively prevent a shortage or an excess of air in each of the zones Z in the temperature controlling space 53.

Based on the operation of each of the blowers 65, each of the supply holes 64 can satisfactorily eject the air for each of the plurality of zones Z of the temperature controlling space 53 (along the circumferential direction of the supply area SA at the same axial position). On the other hand, the plurality of exhaust holes 73 provided along the axial direction of the furnace body 50 can satisfactorily exhaust the air for each of the plurality of zones Z of the temperature controlling space 53 (along the circumferential direction of the exhaust area EA at the same axial position). Accordingly, the processing apparatus 1A continuously supplies the air to flow in the circumferential direction of the outer peripheral surface of the processing chamber 10, and continuously exhausts the air, to thereby maintain the horizontal flow of the air, and efficiently cool the processing chamber 10.

The technical concept and effects of the present disclosure described in the above embodiments will be described in more detail below.

The processing apparatus 1 according to a first aspect of the present invention includes a processing chamber 10 configured to accommodate a substrate W, a furnace body 50, covering a periphery of the processing chamber 10, and configured to heat the substrate W accommodated inside the processing chamber 10, a gas supply unit 60 configured to supply a cooling gas to a temperature controlling space 53 between the processing chamber 10 and the furnace body 50, and a gas discharge unit 70 configured to discharge the gas from the temperature controlling space 53, wherein the processing gas discharge unit 70 includes a plurality of exhaust holes 73 configured to discharge the gas in the temperature controlling space 53, located at a plurality of positions along an axial direction of the furnace body 50 in a sidewall of the furnace body 50.

According to the configuration described above, because the processing apparatus 1 includes the plurality of exhaust holes 73 along the axial direction of the furnace body 50, it is possible to flow the gas through the plurality of exhaust holes 73 arranged in the axial direction in the temperature controlling space 53. In this state, in the temperature controlling space 53, the gas is prevented from moving upward toward the upper portion of the processing chamber 10, and the gas flows along the direction perpendicular to the axial direction of the processing chamber 10, to thereby reduce an unevenness in the temperature caused by the machine difference, the apparatus setup environment, or the like of the processing apparatus 1. For this reason, in the processing apparatus 1, it is possible to promote uniform cooling of the processing chamber 10, and it is possible to improve a temperature control performance (or temperature adjusting performance) during the substrate processing.

In addition, the gas supply unit 60 includes the plurality of supply holes 64 for supplying the gas to the temperature controlling space 53, in the sidewall of the furnace body 50 along the axial direction of the furnace body 50, and the plurality of supply holes 64 and the plurality of exhaust holes 73 are provided for each of the plurality of zones Z set in the axial direction of the temperature controlling space 53. Accordingly, in each of the plurality of zones Z, the processing apparatus 1 can discharge the gas through the exhaust holes 73 and supply the gas from the supply holes 64 to the temperature controlling space 53, and can smoothly form the flow of the gas along the direction perpendicular to the axial direction of the processing chamber 10.

Moreover, the axis of the processing chamber 10 and the axis of the furnace body 50 extend along the vertical direction, and the plurality of supply holes 64 and the plurality of exhaust holes 73 are disposed at the same vertical positions of the furnace body 50. Accordingly, the processing apparatus 1 can stably move the gas along an approximately horizontal direction in the temperature controlling space 53, and can further promote the uniform cooling of the processing chamber 10.

Further, the temperature controlling space 53 is partitioned into the plurality of zones Z by the plurality of partitioning members 55. Hence, the processing apparatus 1 can satisfactorily perform the temperature control for each of the plurality of zones Z.

In addition, one of the plurality of exhaust holes 73 arranged in the axial direction of the furnace body 50 is disposed at the position higher than or equal to the uppermost portion of the plurality of substrates W accommodated inside the processing chamber 10, and another one of the plurality of exhaust holes 73 arranged in the axial direction of the furnace body 50 is disposed at the position lower than or equal to the lowermost portion of the plurality of substrates W accommodated inside the processing chamber 10. Thus, the processing apparatus 1 can stably lower the temperature of all of the plurality of substrates W arranged in the axial direction, and can reduce the unevenness in the process (or unevenness in the deposition) of the substrate processing for each of the substrates W.

The furnace body 50 includes the supply area SA having the plurality of supply holes 64, and the exhaust area EA having the plurality of exhaust holes 73, along the circumferential direction at the same axial position of the furnace body 50. Hence, the processing apparatus 1 can discharge a large amount of gas from the exhaust area EA, and supply a large amount of gas from the gas supply area SA.

The supply area SA and the exhaust area EA are disposed at positions opposite to each other across the center of the furnace body 50. For this reason, in the processing apparatus 1, by guiding the gas supplied from the gas supply area SA to the exhaust area EA on the opposite side in the temperature controlling space 53, the gas can easily be supplied to the outer peripheral surface of the processing chamber 10 during this guiding process, and it is possible to more efficiently cool the substrates W in the processing chamber 10.

The dividing area DA is provided between the supply area SA and the exhaust area EA, to separate the supply area SA and the exhaust area EA from each other. Hence, the processing apparatus 1 can flow the gas to positively flow around the outer peripheral surface of the processing chamber 10, to thereby satisfactorily cool the substrates W in the processing chamber 10.

In addition, the processing gas supply unit 60A includes the plurality of branch paths 61a connected to the plurality of supply holes 64 provided along the axial direction of the furnace body 50, respectively, and further includes, the fan parts (blower 65) that blow the gas to the plurality of supply holes 64 while controlling the flow rate, provided with respect to the plurality of branch paths 61a, respectively. Accordingly, the processing apparatus 1A can stably supply the gas at the target flow rate with respect to each of the zones Z in the furnace body 50 by each of the blowers 65.

Moreover, the processing gas supply unit 60A includes the merged path 61a where the plurality of branch paths 61b merge, and the merged path 61b is connected to the external exhaust path 71 connected to the plurality of exhaust holes 73 in the processing gas discharge unit 70. For this reason, the processing apparatus 1A can circulate the gas between the processing gas supply unit 60A and the processing gas discharge unit 70, so that the temperature of the temperature controlling space 53 can be effectively controlled, and the effects on the environment can be minimized.

Further, the furnace body 50 includes the plurality of exhaust holes 73 along the circumferential direction at the same axial position of the furnace body 50. Thus, the processing apparatus 1 can smoothly discharge the gas in the temperature controlling space 53 using the plurality of exhaust holes 73 disposed along the circumferential direction.

The temperature control method according to a second aspect of the present disclosure includes (a) heating a substrate W accommodated inside a processing chamber 10 by a furnace body 50 that covers a periphery of the processing chamber 10, (b) supplying a cooling gas to a temperature controlling space 53 between the processing chamber 10 and the furnace body 50, and discharging the gas from the temperature controlling space 53, wherein in (b), the discharging discharges the gas in the temperature controlling space 53 from a plurality of exhaust holes 73 located at a plurality of positions along an axial direction of the furnace body 50 in a sidewall of the furnace body 50. The temperature control method described above can also promote the uniform cooling of the processing chamber.

The processing apparatus 1 and the temperature control method according to the embodiments disclosed herein are illustrative in all respects and are not restrictive. Various variations, modifications, and improvements of the embodiments can be made without departing from the scope and spirit of the present invention recited in appended claims, for example. The features and configurations of the embodiments can also be modified as long as there is no contradiction, and the features and configurations can be combined as long as there is no contradiction.

In the processing apparatus 1, the configuration inside the processing chamber 10 is not particularly limited. As an example, the processing apparatus 1 may be a horizontal processing apparatus in which a plurality of substrates W are arranged in the horizontal direction, perpendicular to the vertical direction, inside the processing chamber 10. Even in this case, the furnace body 50 provided outside the processing chamber 10 can uniformly cool the substrates W inside the processing chamber 10. Alternatively, the processing apparatus 1 may have the same configuration in a case where the furnace body 50 is provided outside a single wafer processing chamber 10.

According to the present disclosure, it is possible to provide a technique that promotes uniform cooling of the processing chamber.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A processing apparatus comprising:
a processing chamber configured to accommodate a substrate;
a furnace body, covering a periphery of the processing chamber, and configured to heat the substrate accommodated inside the processing chamber;
a gas supply unit configured to supply a cooling gas to a temperature controlling space between the processing chamber and the furnace body; and
a gas discharge unit configured to discharge the gas from the temperature controlling space,
wherein the processing gas discharge unit includes a plurality of exhaust holes configured to discharge the gas in the temperature controlling space, located at a plurality of positions along an axial direction of the furnace body in a sidewall of the furnace body.

2. The processing apparatus as claimed in claim 1, wherein
the processing gas supply unit includes a plurality of supply holes configured to supply the gas to the temperature controlling space, located at a plurality of positions along the axial direction of the furnace body in the sidewall of the furnace body, and
the plurality of supply holes and the plurality of exhaust holes are provided for each of a plurality of zones set along the axial direction of the temperature controlling space, respectively.

3. The processing apparatus as claimed in claim 2, wherein
an axis of the processing chamber and an axis of the furnace body extend along a vertical direction, and
the plurality of supply holes and the plurality of exhaust holes are located at identical positions along the vertical position of the furnace body, respectively.

4. The processing apparatus as claimed in claim 2, wherein the temperature controlling space is partitioned into the plurality of zones by a plurality of partitioning members, respectively.

5. The processing apparatus as claimed in claim 2, wherein
one of the plurality of exhaust holes arranged along the axial direction of the furnace body is disposed at a position higher than or equal to an uppermost portion of the plurality of substrates accommodated inside the processing chamber, and
another one of the plurality of exhaust holes arranged along the axial direction of the furnace body is disposed at a position lower than or equal to a lowermost portion of the plurality of substrates accommodated inside the processing chamber.

6. The processing apparatus as claimed in claim 2, wherein the furnace body includes a supply area having the plurality of supply holes, and an exhaust area having the plurality of exhaust holes, located along a circumferential direction at identical positions in the axial position of the furnace body, respectively.

7. The processing apparatus as claimed in claim 6, wherein the supply area and the exhaust area are disposed at positions opposite to each other across a center of the furnace body.

8. The processing apparatus as claimed in claim 6, wherein a dividing area configured to separate the supply area and the exhaust area, is provided between the supply area and the exhaust area.

9. The processing apparatus as claimed in claim 2, wherein the supply unit includes
a plurality of branch paths connected to the plurality of supply holes provided along the axial direction of the furnace body, respectively, and
a blower configured to blow the gas to each of the plurality of supply holes while controlling a flow rate, provided for each of the plurality of branch paths.

10. The processing apparatus as claimed in claim 9, wherein
the processing gas supply unit includes a merged path into which the plurality of branch paths merge, and
the merged path is connected to an external exhaust path that connect to the plurality of exhaust holes of the processing gas discharge unit.

11. The processing apparatus as claimed in claim 1, wherein the furnace body includes the plurality of exhaust holes located along a circumferential direction at identical positions in the axial position of the furnace body, respectively.

12. A temperature control method comprising:
heating a substrate accommodated inside a processing chamber by a furnace body that covers a periphery of the processing chamber;
supplying a cooling gas to a temperature controlling space between the processing chamber and the furnace body; and
discharging the gas from the temperature controlling space,
wherein the discharging discharges the gas in the temperature controlling space from a plurality of exhaust holes located at a plurality of positions along an axial direction of the furnace body in a sidewall of the furnace body.

13. The temperature control method as claimed in claim 12, wherein
the supplying supplies the cooling gas from a plurality of supply holes located at a plurality of positions along the axial direction of the furnace body in the sidewall of the furnace body, and
the plurality of supply holes and the plurality of exhaust holes are provided for each of a plurality of zones set along the axial direction of the temperature controlling space, respectively.
